(19) United States
(12) Patent Application Publication
(10) Pub. No.: US 2023/0257295 A1
(43) Pub. Date: Aug. 17, 2023

(54) ALKALI-FREE GLASS PANEL

(71) Applicant: Nippon Electric Glass Co., Ltd., Shiga (JP)

(72) Inventor: Mayu NISHIMIYA, Shiga (JP)

(21) Appl. No.: 18/010,589

(22) PCT Filed: Jun. 15, 2021
(86) PCT No.: PCT/JP2021/022676

§ 371 Date: Dec. 15, 2022

(30) Foreign Application Priority Data
Jun. 18, 2020 (JP) 2020-105253

(51) Int. Cl. C03C 3/091

(52) U.S. Cl. CPC C03C 3/091

(57) ABSTRACT

The present invention provides an alkali-free glass sheet, which has a content of Li₂O+Na₂O+K₂O of from 0 mol % to 0.5 mol % in a glass composition, and has a Young's modulus of 80 GPa or more, a strain point of 700° C. or more, and a liquidus temperature of 1,350° C. or less.

### TECHNICAL FIELD

The present invention relates to an alkali-free glass sheet, and more specifically, to an alkali-free glass sheet suitable for an OLED display.

### BACKGROUND ART

An electronic device such as an OLED display is used in applications, such as a flexible device and a display of a cellular phone, because the electronic device is thin, is excellent in displaying a moving image, and has low power consumption.

A glass sheet is widely used as a substrate of an OLED display. The glass sheet for this application is mainly required to satisfy the following characteristics.
(1) To be substantially free of an alkali metal oxide, that is, to be alkali-free glass (to have a content of an alkali metal oxide of 0.5 mol % or less in a glass composition) in order to prevent a situation in which an alkali ion is diffused in a heat treatment step into a semiconductor substance having been formed into a film.
(2) To be excellent in productivity, particularly excellent in meltability and devitrification resistance in order to achieve a reduction in cost of the glass sheet.
(3) To have a high strain point in order to reduce the thermal shrinkage of the glass sheet in a low temperature polysilicon (LTPS) process or an oxide thin film transistor (TFT) process.

### CITATION LIST

Patent Literature 1: JP 2012-106919 A

### SUMMARY OF INVENTION

### Technical Problem

Incidentally, an OLED device has been widely deployed also in an OLED TV. There are strong demands for an increase in size and a reduction in thickness of the OLED TV, and there is an increasing demand for a display having a high resolution of 8 K or the like. Accordingly, a glass sheet for those applications is required to have such thermal dimensional stability as to be able to withstand the high resolution demand while achieving an increase in size and a reduction in thickness. Further, in order to reduce a difference in price from a liquid crystal display, a further reduction in cost is required, and also the glass sheet is similarly required to be reduced in cost. However, when the glass sheet is increased in size and reduced in thickness, the glass sheet is liable to be deflected, and a manufacturing cost rises.

The glass sheet formed by a glass manufacturer is subjected to, for example, cutting, annealing, testing, and washing steps, and during these steps, the glass sheet is loaded into a cassette in which a plurality of shelves are formed and is discharged therefrom. The cassette is generally configured so that pairing two sides of the glass sheet are placed on shelves formed on left and right inner surfaces of the cassette to allow the glass sheet to be held in a horizontal direction. However, a large and thin glass sheet has a large deflection amount, and hence at the time of loading of the glass sheet into the cassette, part of the glass sheet is brought into contact with the cassette, and the glass sheet is liable to be broken. At the time of discharge, the glass sheet largely swings and is liable to be unstable. The cassette having such configuration is also used in an electronic device manufacturer, resulting in occurrence of similar defects. In order to solve the above-mentioned problems, a method involving increasing the Young's modulus of the glass sheet, to thereby reduce the deflection amount thereof is effective.

In addition, as described above, it is required that the strain point of the glass sheet be increased in order to reduce the thermal shrinkage of a large glass sheet in the LTPS process or the oxide TFT process for obtaining a display having a high resolution.

However, when the Young's modulus and the strain point of the glass sheet are to be increased, the glass composition loses its balance, with the result that productivity is reduced, and particularly the devitrification resistance is liable to be remarkably reduced. In addition, the meltability is reduced or a glass forming temperature is increased, with the result that the lifetime of a forming trough is liable to be shortened. As a result, the raw sheet cost of the glass sheet rises.

Thus, the present invention has been devised in view of the above-mentioned circumstances, and a technical object of the present invention is to provide an alkali-free glass sheet which is excellent in productivity and has a sufficiently high strain point and a sufficiently high Young's modulus.

### Solution to Problem

The inventor of the present invention has repeated various experiments, and as a result, has found that the above-mentioned technical object can be achieved by strictly restricting the glass characteristics of an alkali-free glass sheet. Thus, the finding is proposed as the present invention. That is, according to one embodiment of the present invention, there is provided an alkali-free glass sheet, which has a content of Li₂O+Na₂O+K₂O of from 0 mol % to 0.5 mol % in a glass composition, and has a Young's modulus of 80 GPa or more, a strain point of 700° C. or more, and a liquidus temperature of 1,350° C. or less. Herein, the “Li₂O+Na₂O+K₂O” refers to the total content of Li₂O, Na₂O, and K₂O. The “Young's modulus” refers to a value measured by a flexural resonance method. 1 GPa corresponds to about 101.9 Kgf/mm². The “strain point” refers to a value measured based on a method of ASTM C336. The “liquidus temperature” refers to a temperature at which a crystal precipitates after glass powder having passed through a standard 30-mesh sieve (500 μm) and remained on a 50-mesh sieve (300 μm) is placed in a platinum boat and kept for 24 hours in a gradient heating furnace.

According to another embodiment of the present invention, there is provided an alkali-free glass sheet, comprising as a glass composition, in terms of mol %, 64% to 71% of SiO₂, 12% to 17% of Al₂O₃, 0% to 5% of B₂O₃, 0% to 0.5% of Li₂O+Na₂O+K₂O, 5% to 9% of MgO, 2% to 10% of CaO, 0% to 7% of SrO, more than 1% to 7% of BaO, and 14% to 20% of MgO+CaO+SrO+BaO, and having a molar ratio Al₂O₃/BaO of from 1.8 to 10, a molar ratio B₂O₃/(MgO+CaO+SrO+BaO) of from 0 to 0.2, a molar ratio (B₂O₃+MgO)/SiO₂ of from 0.1 to 0.2, and a molar ratio B₂O₃/MgO of from 0 to 0.5. Herein, the “MgO+CaO+SrO+BaO” refers to the total content of MgO, CaO, SrO, and BaO. The “Al₂O₃/BaO” refers to a value obtained by dividing the content of Al₂O₃ by the content of BaO. The “B₂O₃/(MgO+CaO+SrO+BaO)” refers to a value obtained by dividing the content of B₂O₃ by the total content of MgO, CaO, SrO, and BaO. The “(B₂O₃+MgO)/SiO₂” refers to a value obtained by dividing the total content of B₂O₃ and MgO by the content of SiO₂. The “B₂O₃/MgO” refers to a value obtained by dividing the content of B₂O₃ by the content of MgO.

In addition, it is preferred that the alkali-free glass sheet according to any one of the embodiments of the present invention be further substantially free of As₂O₃ and Sb₂O₃. Herein, the “substantially free of As₂O₃ and Sb₂O₃” refers to the case in which the contents of As₂O₃ and Sb₂O₃ in the glass composition are each less than 0.05%.

In addition, it is preferred that the alkali-free glass sheet according to any one of the embodiments of the present invention further comprise 0.001 mol % to 1 mol % of SnO₂.

In addition, it is preferred that the alkali-free glass sheet according to any one of the embodiments of the present invention have a strain point of 710° C. or more.

In addition, it is preferred that the alkali-free glass sheet according to any one of the embodiments of the present invention have a Young's modulus of more than 81 GPa.

In addition, it is preferred that the alkali-free glass sheet according to any one of the embodiments of the present invention have an average thermal expansion coefficient within a temperature range of from 30° C. to 380° C. of from 30×10⁻⁷/° C. to 50×10⁻⁷/° C. Herein, the “average thermal expansion coefficient within a temperature range of from 30° C. to 380° C.” may be measured with a dilatometer.

In addition, it is preferred that the alkali-free glass sheet according to any one of the embodiments of the present invention have a liquidus viscosity of 10^{4.0} dPa·s or more. Herein, the “liquidus viscosity” refers to a glass viscosity at the liquidus temperature, and may be measured by a platinum sphere pull up method.

In addition, it is preferred that the alkali-free glass sheet according to any one of the embodiments of the present invention be used for an OLED device.

### DESCRIPTION OF EMBODIMENTS

An alkali-free glass sheet of the present invention comprises as a glass composition, in terms of mol %, 64% to 71% of SiO₂, 12% to 17% of Al₂O₃, 0% to 5% of B₂O₃, 0% to 0.5% of Li₂O+Na₂O+K₂O, 5% to 9% of MgO, 2% to 10% of CaO, 0% to 7% of SrO, more than 1% to 7% of BaO, and 14% to 20% of MgO+CaO+SrO+BaO, and having a molar ratio Al₂O₃/BaO of from 1.8 to 10, a molar ratio B₂O₃/(MgO+CaO+SrO+BaO) of from 0 to 0.2, a molar ratio (B₂O₃+MgO)/SiO₂ of from 0.1 to 0.2, and a molar ratio B₂O₃/MgO of from 0 to 0.5. The reasons why the contents of the components are limited as described above are described below. In the descriptions of the contents of the components, the expression “%” represents “mol %”, unless otherwise specified.

SiO₂ is a component which forms the skeleton of glass. When the content of SiO₂ is too small, a thermal expansion coefficient is increased, and a density is increased. Accordingly, the lower limit content of SiO₂ is preferably 64%, still more preferably 64.2%, still more preferably 64.4%, still more preferably 64.6%, still more preferably 64.8%, still more preferably 65%, most preferably 65.2%. Meanwhile, when the content of SiO₂ is too large, a Young's modulus is reduced. Further, a viscosity at high temperature is increased, resulting in an increase in amount of heat required for melting. This causes a rise in melting cost, and in addition, leads to occurrence of defects due to an unmelted residue of a SiO₂ raw material, which may cause a reduction in yield. In addition, a devitrified crystal such as cristobalite is liable to precipitate, and a liquidus viscosity is liable to be reduced. Accordingly, the upper limit content of SiO₂ is preferably 71%, still more preferably 70.8%, still more preferably 70.6%, still more preferably 71.4%, still more preferably 70.2%, still more preferably 70%, most preferably 69.8%.

Al₂O₃ is a component which forms the skeleton of the glass, and is also a component which increases the Young's modulus, and is further a component which increases a strain point. When the content of Al₂O₃ is too small, the Young's modulus is liable to be reduced, and the strain point is liable to be reduced. Accordingly, the lower limit content of Al₂O₃ is preferably 12%, more preferably more than 12%, more preferably 12.1%, still more preferably 12.2%, still more preferably 12.5%, still more preferably 12.6%, still more preferably 12.8%, most preferably 13%. Meanwhile, when the content of Al₂O₃ is too large, a devitrified crystal such as mullite is liable to precipitate, and the liquidus viscosity is liable to be reduced. Accordingly, the upper limit content of Al₂O₃ is preferably 17%, more preferably 16.8%, more preferably 16.6%, still more preferably 16.4%, still more preferably 16.2%, most preferably 16%.

B₂O₃ is a component which improves the meltability and the devitrification resistance. When the content of B₂O₃ is too small, the meltability and the devitrification resistance are liable to be reduced. Accordingly, the lower limit content of B₂O₃ is preferably 0%, more preferably more than 0%, more preferably 0.1%, still more preferably 0.2%, still more preferably 0.3%, still more preferably 0.4%, most preferably more than 1%. Meanwhile, when the content of B₂O₃ is too large, the Young's modulus and the strain point are liable to be reduced. Accordingly, the upper limit content of B₂O₃ is preferably 5%, more preferably 4.8%, more preferably 4.6%, still more preferably 4.4%, still more preferably 4.2%, most preferably 4%.

Li₂O, Na₂O, and K₂O are each a component which is inevitably mixed in from glass raw materials, and the total content thereof is preferably from 0% to 0.5%, more preferably from 0% to 0.3%, most preferably from 0% to 0.2%. When the total content of Li₂O, Na₂O, and K₂O is too large, a situation in which an alkali ion is diffused in a heat treatment step into a semiconductor substance having been formed into a film may occur.

MgO is a component which remarkably increases the Young's modulus among alkaline earth metal oxides. When the content of MgO is too small, the meltability and the Young's modulus are liable to be reduced. Accordingly, the lower limit content of MgO is preferably 5%, more preferably 5.1%, more preferably 5.2%, still more preferably 5.3%, still more preferably 5.4%, still more preferably 5.5%, still more preferably 5.6%, most preferably 5.7%. Meanwhile, when the content of MgO is too large, a devitrified crystal such as mullite is liable to precipitate, and the liquidus viscosity is liable to be reduced. Accordingly, the upper limit content of MgO is preferably 9%, more preferably 8.9%, more preferably 8.8%, still more preferably 8.7%, still more preferably 8.6%, still more preferably 8.5%, still more preferably less than 8.5%, still more preferably 8.4%, most preferably less than 8.4%.

CaO is a component which reduces the viscosity at high temperature to remarkably improve the meltability without reducing the strain point. CaO is also a component which increases the Young's modulus. When the content of CaO is too small, it becomes difficult to exhibit the above-mentioned effects, and the meltability is liable to be reduced. Further, the devitrification resistance is liable to be reduced. Accordingly, the lower limit content of CaO is preferably 2%, more preferably 2.2%, more preferably 2.4%, still more preferably 2.5%, still more preferably 2.6%, still more preferably 2.8%, still more preferably 3%, most preferably more than 3%. Meanwhile, when the content of CaO is too large, the liquidus temperature is increased. Accordingly, the upper limit content of CaO is preferably 10%, more preferably 9.9%, more preferably 9.8%, still more preferably 9.7%, still more preferably 9.6%, still more preferably 9.5%, still more preferably 9.4%, still more preferably 9.3%, most preferably 9.2%.

SrO is a component which improves the devitrification resistance, and is further a component which reduces the viscosity at high temperature to improve the meltability without reducing the strain point. SrO is also a component which suppresses a reduction in liquidus viscosity. When the content of SrO is too small, it becomes difficult to exhibit the above-mentioned effects. Accordingly, the lower limit content of SrO is preferably 0%, more preferably more than 0%, more preferably 0.1%, still more preferably more than 0.1%, still more preferably 0.2%, still more preferably 0.3%, still more preferably more than 0.3%, still more preferably 0.4%, most preferably more than 0.4%. Meanwhile, when the content of SrO is too large, the thermal expansion coefficient and the density are liable to be increased. Accordingly, the upper limit content of SrO is preferably 6%, more preferably less than 6%, more preferably 5.9%, still more preferably less than 5.9%, still more preferably 5.8%, still more preferably less than 5.8%, still more preferably 5.7%, still more preferably less than 5%, still more preferably less than 4%, most preferably 3%.

BaO is a component which improves the devitrification resistance. When the content of BaO is too small, it becomes difficult to exhibit the above-mentioned effect. Accordingly, the lower limit content of BaO is preferably more than 1%, more preferably 1.1%, more preferably 1.2%, still more preferably 1.3%, still more preferably 1.4%, still more preferably 1.5%, still more preferably 1.6%, most preferably 1.7%. Meanwhile, when the content of BaO is too large, the Young's modulus is liable to be reduced, and the thermal expansion coefficient and the density are liable to be increased. Accordingly, the upper limit content of BaO is preferably 7%, more preferably 6.8%, more preferably 6.6%, still more preferably 6.4%, still more preferably 6.2%, still more preferably 6%, most preferably less than 6%.

Both an excessively small total content and an excessively large total content of MgO, CaO, SrO,and BaO are liable to cause a reduction in meltability. When the total content of MgO, CaO, SrO and BaO is too small, the meltability is liable to be reduced, and also the Young's modulus is liable to be reduced. Accordingly, the lower limit of the total content of MgO, CaO, SrO and BaO is preferably 14%, more preferably 14.5%, more preferably 15%, still more preferably 15.3%, still more preferably 15.5%, still more preferably 15.8%, still more preferably 15.9%, most preferably 16%. Meanwhile, when the total content of MgO, CaO, SrO, and BaO is too large, the thermal expansion coefficient and the density are liable to be increased. Accordingly, the upper limit of the total content of MgO, CaO, SrO, and BaO is preferably 20%, more preferably 19.8%, more preferably 19.6%, still more preferably 19.4%, still more preferably 19.2%, still more preferably 19%, most preferably less than 19%.

When a molar ratio Al₂O₃/BaO is too small, the Young's modulus is liable to be reduced. Accordingly, the lower limit value of the molar ratio Al₂O₃/BaO is preferably 1.8, more preferably 2, more preferably 3, still more preferably 4, still more preferably 4.5, most preferably 5. When the molar ratio Al₂O₃/BaO is too large, the liquidus viscosity is liable to be reduced. Accordingly, the upper limit value of the molar ratio Al₂O₃/BaO is preferably 10, more preferably 9.8, more preferably 9.6, still more preferably 9.4, still more preferably 9.2, most preferably 9.

When a molar ratio B₂O₃/(MgO+CaO+SrO+BaO) is too small, the meltability is liable to be reduced. Accordingly, the lower limit value of the molar ratio B₂O₃/(MgO+CaO+SrO+BaO) is preferably 0, more preferably more than 0, more preferably 0.01, still more preferably 0.02, still more preferably 0.03, most preferably 0.04. When the molar ratio B₂O₃/(MgO+CaO+SrO+BaO) is too large, the strain point is liable to be reduced. Accordingly, the upper limit value of the molar ratio B₂O₃/(MgO+CaO'SrO+BaO) is preferably 0.2, more preferably 0.19, more preferably 0.18, still more preferably 0.17, still more preferably 0.16, most preferably 0.15.

When a molar ratio (B₂O₃+MgO)/SiO₂ is too small, the meltability is liable to be reduced. Accordingly, the lower limit value of the molar ratio (B₂O₃+MgO)/SiO₂ is preferably 0.1, more preferably more than 0.1, more preferably 0.11, still more preferably 0.12, still more preferably 0.13, most preferably 0.14. When the molar ratio (B₂O₃+MgO)/SiO₂ is too large, the strain point is liable to be reduced. Accordingly, the upper limit value of the molar ratio (B₂O₃+MgO)/SiO₂ is preferably 0.2, more preferably less than 0.2, more preferably 0.19, still more preferably 0.18, still more preferably 0.17, most preferably 0.16.

A molar ratio B₂O₃/MgO is an important component ratio for achieving a high Young's modulus, high meltability, a low thermal shrinkage rate, and productivity. When the molar ratio B₂O₃/MgO is too small, the liquidus temperature is increased to reduce the productivity, the meltability is liable to be reduced, and a glass forming temperature is increased to shorten the lifetime of a forming trough. As a result, the cost of the glass rises. Accordingly, the lower limit value of the molar ratio B₂O₃/MgO is preferably 0, more preferably more than 0, more preferably 0.03, still more preferably 0.05, still more preferably 0.08, most preferably 0.1. When the molar ratio B₂O₃/MgO is too large, the strain point is reduced, with the result that high thermal dimensional stability is not obtained, and the Young's modulus is reduced, with the result that a large glass sheet is liable to be deflected. Accordingly, the upper limit value of the molar ratio B₂O₃/MgO is preferably 0.5, more preferably 0.48, more preferably 0.46, still more preferably 0.44, still more preferably 0.42, still more preferably 0.40, still more preferably 0.37, still more preferably 0.36, still more preferably 0.35, still more preferably 0.33, most preferably 0.30.

For example, the following components may be added as optional components in addition to the above-mentioned components. The content of the components other than the above-mentioned components, in terms of total content, is preferably 10% or less, particularly preferably 5% or less from the viewpoint of appropriately exhibiting the effects of the present invention.

P₂O₅ is a component which increases the strain point, and is also a component which can remarkably suppress the precipitation of an alkaline earth aluminosilicate-based devitrified crystal such as anorthite. However, when P₂O₅ is contained in a large amount, the glass is liable to undergo phase separation. The content of P₂O₅ is preferably from 0% to 2.5%, more preferably from 0.0005% to 1.5%, still more preferably from 0.001% to 0.5%, particularly preferably from 0.005% to 0.3%.

TiO₂ is a component which reduces the viscosity at high temperature to improve the meltability, and is also a component which suppresses solarization. However, when TiO₂ is contained in a large amount, the glass is colored, and thus a transmittance is liable to be reduced. The content of TiO₂ is preferably from 0% to 2.5%, more preferably from 0.0005% to 1%, still more preferably from 0.001% to 0.5%, particularly preferably from 0.005% to 0.1%.

ZnO is a component which increases the meltability. However, when ZnO is contained in a large amount, the glass is liable to devitrify, and in addition, the strain point is liable to be reduced. The content of ZnO is preferably from 0% to 6%, from 0% to 5%, or from 0% to 4%, particularly preferably from 0% to less than 3%.

Y₂O₃, Nb₂O₅, and La₂O₃ each have an action of increasing the strain point, the Young's modulus, and the like. The total content and the individual contents of those components are each preferably from 0% to 5%, more preferably from 0% to 1%, still more preferably from 0% to 0.5%. When the total content and the individual contents of Y₂O₃, Nb₂O₅, and La₂O₃ are too large, the density and raw material cost are liable to be increased.

SnO₂ is a component which exhibits a satisfactory fining action in a high temperature region. In addition, SnO₂ is a component which increases the strain point, and is also a component which reduces the viscosity at high temperature. The content of SnO₂ is preferably from 0% to 1%, from 0.001% to 1%, or from 0.01% to 0.5%, particularly preferably from 0.05% to 0.3%. When the content of SnO₂ is too large, a devitrified crystal of SnO₂ is liable to precipitate. When the content of SnO₂ is less than 0.001%, it becomes difficult to exhibit the above-mentioned effects.

SnO₂ is suitable as a fining agent as described above, but unless glass characteristics are impaired, F, SO₃, C, or metal powder of Al, Si, or the like may each be added as a fining agent in place of SnO₂ or together with SnO₂ at up to 5% (preferably up to 1%, particularly preferably up to 0.5%). In addition, CeO₂ or the like may also be added as a fining agent at up to 5% (preferably up to 1%, particularly preferably up to 0.5%).

As₂O₃ and Sb₂O₃ are each effective as a fining agent as well. However, the alkali-free glass sheet of the present invention is substantially free of those components from an environmental viewpoint. Further, when As₂O₃ is contained, solarization resistance tends to be reduced.

Cl is a component which promotes initial melting of a glass batch. In addition, when Cl is added, the action of the fining agent can be promoted. As a result thereof, while the melting cost is reduced, the lifetime of a glass production kiln can be prolonged. However, when the content of Cl is too large, the strain point is liable to be reduced. Accordingly, the content of Cl is preferably from 0% to 3%, more preferably from 0.0005% to 1%, particularly preferably from 0.001% to 0.5%. The following raw material may be used as a raw material for introducing Cl: an alkaline earth metal chloride such as strontium chloride, aluminum chloride, or the like.

Fe₂O₃ is a component which is mixed in as a raw material impurity, and is also a component which reduces an electrical resistivity. The content of Fe₂O₃ is preferably from 0 ppm by mass to 300 ppm by mass or from 80 ppm by mass to 250 ppm by mass, particularly preferably from 100 ppm by mass to 200 ppm by mass. When the content of Fe₂O₃ is too small, the raw material cost is liable to rise. Meanwhile, when the content of Fe₂O₃ is too large, it becomes difficult to perform electric melting owing to an increase in electrical resistivity of the molten glass.

A particularly preferred glass composition range is as follows: the alkali-free glass sheet comprises, in terms of mol %, 65% to 70% of SiO₂, 12.5% to 16% of Al₂O₃, 0% to 4% of B₂O₃, 0% to 0.5% of Li₂O+Na₂O+K₂O, 5.7% to 9% of MgO, 3% to 10% of CaO, 0% to 6% of SrO, more than 1% to 6% of BaO, and 16% to 19% of MgO+CaO+SrO+BaO, and has a molar ratio Al₂O₃/BaO of from 2 to 9, a molar ratio B₂O₃/(MgO+CaO+SrO+BaO) of from 0 to 0.15, a molar ratio (B₂O₃+MgO)/SiO₂ of from 0.1 to 0.2, and a molar ratio B₂O₃/MgO of from 0.1 to 0.36. With this configuration, while a high Young's modulus, a high strain point, and high heat resistance (high thermal dimensional stability) are ensured, the productivity can be increased.

The alkali-free glass sheet of the present invention preferably has the following characteristics.

The average thermal expansion coefficient within a temperature range of from 30° C. to 380° C. is preferably from 30×10⁻⁷/° C. to 50×10⁻⁷/° C., from 32×10⁻⁷/° C. to 48×10⁻⁷/° C., from 33×10⁻⁷/° C. to 45×10⁻⁷/° C., or from 34×10⁻⁷/° C. to 44×10⁻⁷/° C., particularly preferably from 35×10⁻⁷/° C. to 43×10⁻⁷/° C. With this configuration, the thermal expansion coefficient easily matches the thermal expansion coefficient of Si to be used for a TFT.

The Young's modulus is 80 GPa or more, preferably more than 80 GPa, 81 GPa or more, more than 81 GPa, more than 82 GPa, 83 GPa or more, or 84 GPa or more, particularly preferably from more than 84 GPa to 95 GPa. When the Young's modulus is too low, defects due to the deflection of the glass sheet are liable to occur.

The strain point is 700° C. or more, preferably more than 700° C., or 705° C. or more, particularly preferably from 710° C. to 770° C. With this configuration, the thermal shrinkage of the glass sheet can be suppressed in an LTPS process.

The liquidus temperature is 1,350° C. or less, preferably less than 1,350° C., or 1,300° C. or less, particularly preferably from 800° C. to 1,280° C. With this configuration, a situation in which a devitrified crystal is generated at the time of glass manufacture, resulting in a reduction in productivity, is easily prevented. Further, the glass sheet is easily formed by an overflow down-draw method, and hence the surface quality of the glass sheet is easily improved. Besides, the manufacturing cost of the glass sheet can be reduced. The liquidus temperature serves as an indicator of the devitrification resistance. As the liquidus temperature becomes lower, the devitrification resistance is more excellent.

The liquidus viscosity is preferably 10^{4.0} dPa·s or more, 10^{4.1} dPa·s or more, or 10^{4.2} dPa·s or more, particularly preferably 10^{4.3} dPa·s or more. With this configuration, devitrification is less liable to occur at the time of forming, and hence the glass sheet is easily formed by an overflow down-draw method. As a result, the surface quality of the glass sheet can be improved. Besides, the manufacturing cost of the glass sheet can be reduced. The liquidus viscosity serves as indicators of the devitrification resistance and the formability. As the liquidus viscosity becomes higher, the devitrification resistance and the formability are improved more.

The temperature at a viscosity at high temperature of 10^{2.5} dPa·s is preferably 1,650° C. or less, 1,630° C. or less, or 1,610° C. or less, particularly preferably 1,600° C. or less. When the temperature at a viscosity at high temperature of 10^{2.5} dPa·s is too high, it becomes difficult to melt a glass batch, resulting in a rise in manufacturing cost of the glass sheet. The temperature at a viscosity at high temperature of 10^{2.5} dPa·s corresponds to a melting temperature. As the temperature becomes lower, the meltability is improved more.

The β-OH is an indicator of the amount of water in the glass. When the β-OH is reduced, the strain point can be increased. In addition, even with the same glass composition, a glass sheet having lower β-OH has a lower thermal shrinkage rate at a temperature equal to or lower than the strain point. The β-OH is preferably 0.35/mm or less, 0.30/mm or less, 0.28/mm or less, or 0.25/mm or less, particularly preferably 0.20/mm or less. When the β-OH is too low, the meltability is liable to be reduced. Accordingly, the β-OH is preferably 0.01/mm or more, particularly preferably 0.03/mm or more.

As a method of reducing the β-OH, the following methods are given: (1) a method involving selecting raw materials having low water contents; (2) a method involving adding a component (such as Cl or SO₃) which reduces the β-OH to the glass; (3) a method involving reducing the amount of water in a furnace atmosphere; (4) a method involving performing N₂ bubbling in molten glass; (5) a method involving adopting a small melting furnace; (6) a method involving increasing the flow rate of molten glass; and (7) a method involving adopting an electric melting method.

Herein, the “β-OH” refers to a value determined using the following mathematical formula by measuring the transmittances of the glass with an FT-IR.

β-OH=(1/X)log(T₁/T₂)
X: Thickness (mm)
T₁: Transmittance (%) at a reference wavelength of 3,846 cm⁻¹

T₂: Minimum transmittance (%) at a wavelength around a hydroxyl group absorption wavelength of 3,600 cm⁻¹

It is preferred that the alkali-free glass sheet of the present invention be formed by an overflow down-draw method. The overflow down-draw method refers to a method in which molten glass is caused to overflow from both sides of a heat-resistant trough-shaped structure, and the overflowing molten glass is subjected to down-draw downward at the lower end of the trough-shaped structure while being joined, to thereby manufacture the glass sheet. By the overflow down-draw method, surfaces which are to serve as the surfaces of the glass sheet are formed in a state of free surfaces without being brought into contact with the trough-shaped refractory. As a result, a glass sheet having good surface quality can be manufactured without polishing at low cost, and a reduction in thickness is easily achieved as well.

Other than the overflow down-draw method, the glass sheet may be formed by, for example, a down-draw method (such as a slot down method) or a float method.

The sheet thickness of the alkali-free glass sheet of the present invention is not particularly limited, but is preferably less than 0.7 mm, 0.6 mm or less, or less than 0.6 mm, particularly preferably 0.5 mm or less. As the sheet thickness becomes smaller, the weight saving of an OLED device can be achieved more. The sheet thickness may be adjusted based on, for example, a flow rate and a sheet-drawing speed at the time of glass manufacture.

The alkali-free glass sheet of the present invention is preferably used as a substrate of a display panel for an OLED device, particularly for an OLED TV, or as a carrier for manufacturing an OLED display panel. In OLED TV applications, a plurality of devices are formed on the glass sheet, and the glass sheet is then cut and divided into the respective devices to achieve cost-cutting (so-called multiple patterning). The alkali-free glass sheet of the present invention has a low liquidus temperature and a high liquidus viscosity, and hence a large glass sheet is easily formed, and thus such demand can be appropriately satisfied.

### EXAMPLES

The present invention is hereinafter described by way of Examples. Examples below are merely examples, and the present invention is by no means limited to Examples below.

Examples (Sample Nos. 1 to 12) of the present invention are shown in Table 1. In the table, RO represents MgO+CaO+SrO+BaO. Na₂O is mixed in the glass composition as an inevitable impurity from glass raw materials at from about 0.005 mol % to about 0.02 mol % while not explicitly shown in the table.

TABLE 1

| | | No. 1 | No. 2 | No. 3 | No. 4 | No. 5 | No. 6 |
|---|---|---|---|---|---|---|---|
| Glass | SiO₂ | 65.9 | 65.9 | 65.9 | 65.9 | 65.9 | 65.9 |
| composition | Al₂O₃ | 15.0 | 15.0 | 15.0 | 15.0 | 15.0 | 15.0 |
| (mol %) | B₂O₃ | 2.0 | 2.0 | 2.0 | 2.0 | 2.0 | 2.0 |
| | Li₂O | 0.0 | 0.0 | 0.0 | 0.0 | 0.0 | 0.0 |
| | Na₂O | 0.0 | 0.0 | 0.0 | 0.0 | 0.0 | 0.0 |
| | K₂O | 0.0 | 0.0 | 0.0 | 0.0 | 0.0 | 0.0 |
| | MgO | 7.0 | 7.0 | 7.0 | 8.0 | 8.0 | 8.0 |
| | CaO | 6.0 | 4.0 | 4.0 | 6.0 | 4.0 | 4.0 |
| | SrO | 1.0 | 3.0 | 1.0 | 1.0 | 3.0 | 1.0 |
| | BaO | 3.0 | 3.0 | 5.0 | 2.0 | 2.0 | 4.0 |
| | SnO₂ | 0.1 | 0.1 | 0.1 | 0.1 | 0.1 | 0.1 |
| Li₂O + Na₂O + K₂O | | 0.0 | 0.0 | 0.0 | 0.0 | 0.0 | 0.0 |
| RO | | 17.0 | 17.0 | 17.0 | 17.0 | 17.0 | 17.0 |
| Al₂O₃/BaO | | 5.00 | 5.00 | 3.00 | 7.50 | 7.50 | 3.75 |
| B₂O₃/RO | | 0.12 | 0.12 | 0.12 | 0.12 | 0.12 | 0.12 |
| (B₂O₃₊MgO)/SiO₂ | | 0.14 | 0.14 | 0.14 | 0.15 | 0.15 | 0.15 |
| B₂O₃/MgO | | 0.29 | 0.29 | 0.29 | 0.25 | 0.25 | 0.25 |
| CTE [×10⁻⁷/° C.] | | 38.4 | 39 | 39.3 | 37 | 37.5 | 38 |
| Density [g/cm³] | | 2.61 | 2.64 | 2.67 | 2.58 | 2.61 | 2.64 |
| Young's modulus [GPa] | | 85 | 84 | 84 | 86 | 86 | 85 |
| Ps [° C.] | | 740 | 740 | 740 | 741 | 740 | 740 |
| Ta [° C.] | | 796 | 797 | 797 | 796 | 796 | 796 |
| Ts [° C.] | | 1,016 | 1,018 | 1,020 | 1,013 | 1,016 | 1,017 |
| 10⁴ dPa · s [° C.] | | 1,306 | 1,311 | 1,311 | 1,297 | 1,304 | 1,310 |
| 10³ dPa · s [° C.] | | 1,454 | 1,460 | 1,460 | 1,443 | 1,452 | 1,458 |
| 10^{2.5} dPa · s [° C.] | | 1,549 | 1,556 | 1,556 | 1,537 | 1,547 | 1,555 |
| TL [° C.] | | 1,256 | 1,253 | 1,227 | 1,282 | 1,285 | 1,282 |
| Log₁₀ηTL | | 4.5 | 4.5 | 4.8 | 4.1 | 4.2 | 4.2 |
| | | No. 7 | No. 8 | No. 9 | No. 10 | No. 11 | No. 12 |
| Glass | SiO₂ | 68.9 | 68.9 | 68.9 | 67.9 | 67.9 | 67.9 |
| composition | Al₂O₃ | 13.5 | 13.5 | 13.5 | 13.5 | 13.5 | 13.5 |
| (mol %) | B₂O₃ | 1.0 | 1.0 | 1.0 | 1.0 | 1.0 | 1.0 |
| | Li₂O | 0.0 | 0.0 | 0.0 | 0.0 | 0.0 | 0.0 |
| | Na₂O | 0.0 | 0.0 | 0.0 | 0.0 | 0.0 | 0.0 |
| | K₂O | 0.0 | 0.0 | 0.0 | 0.0 | 0.0 | 0.0 |
| | MgO | 7.0 | 7.0 | 7.0 | 8.0 | 8.0 | 8.0 |
| | CaO | 7.0 | 5.0 | 5.0 | 7.0 | 5.0 | 5.0 |
| | SrO | 0.5 | 2.5 | 0.5 | 0.5 | 2.5 | 0.5 |
| | BaO | 2.0 | 2.0 | 4.0 | 2.0 | 2.0 | 4.0 |
| | SnO₂ | 0.1 | 0.1 | 0.1 | 0.1 | 0.1 | 0.1 |

| | | | | | | |
|---|---|---|---|---|---|---|
| Li₂O + Na₂O + K₂O | 0.0 | 0.0 | 0.0 | 0.0 | 0.0 | 0.0 |
| RO | 16.5 | 16.5 | 16.5 | 17.5 | 17.5 | 17.5 |
| Al₂O₃/BaO | 6.75 | 6.75 | 3.38 | 6.75 | 6.75 | 3.38 |
| B₂O₃/RO | 0.06 | 0.06 | 0.06 | 0.06 | 0.06 | 0.06 |
| (B₂O₃₊MgO)/SiO₂ | 0.12 | 0.12 | 0.12 | 0.13 | 0.13 | 0.13 |
| B₂O₃/MgO | 0.14 | 0.14 | 0.14 | 0.13 | 0.13 | 0.13 |
| CTE [×10⁻⁷/° C.] | 37.1 | 37.5 | 37.7 | 37.7 | 38.3 | 38.7 |
| Density [g/cm³] | 2.56 | 2.59 | 2.62 | 2.57 | 2.60 | 2.63 |
| Young's modulus [GPa] | 86 | 85 | 84 | 87 | 86 | 85 |
| Ps [° C.] | 750 | 749 | 750 | 745 | 745 | 746 |
| Ta [° C.] | 806 | 806 | 807 | 801 | 801 | 802 |
| Ts [° C.] | 1,032 | 1,034 | 1,036 | 1,022 | 1,025 | 1,027 |
| 10⁴ dPa · s [° C.] | 1,336 | 1,343 | 1,348 | 1,318 | 1,324 | 1,329 |
| 10³ dPa · s [° C.] | 1,492 | 1,501 | 1,510 | 1,471 | 1,478 | 1,484 |
| 10^{2.5} dPa · s [° C.] | 1,590 | 1,600 | 1,610 | 1,570 | 1,577 | 1,585 |
| TL [° C.] | 1,273 | 1,262 | 1,262 | 1,280 | 1,267 | 1,278 |
| Log₁₀ηTL | 4.5 | 4.7 | 4.7 | 4.3 | 4.5 | 4.4 |

First, a glass batch prepared by blending glass raw materials so as to achieve each of the glass compositions shown in the table was loaded in a platinum crucible, and then melted at from 1,600° C. to 1,650° C. for 24 hours. In melting the glass batch, molten glass was stirred to be homogenized by using a platinum stirrer. Next, the molten glass was poured on a carbon sheet and formed into a sheet shape, followed by being annealed at a temperature around an annealing point for 30 minutes. Each of the resultant samples was evaluated for its average thermal expansion coefficient CTE within a temperature range of from 30° C. to 380° C., density, Young's modulus, strain point Ps, annealing point Ta, softening point Ts, temperature at a viscosity at high temperature of 10⁴ dPa·s, temperature at a viscosity at high temperature of 10³ dPa·s, temperature at a viscosity at high temperature of 10^{2.5} dPa·s, liquidus temperature TL, and viscosity log₁₀ηTL at the liquidus temperature TL.

The average thermal expansion coefficient CTE within a temperature range of from 30° C. to 380° C. is a value measured with a dilatometer.

The density is a value measured by a well-known Archimedes method.

The Young's modulus refers to a value measured by a well-known resonance method.

The strain point Ps, the annealing point Ta, and the softening point Ts are values measured in accordance with methods specified in ASTM C336 and C338.

The temperatures at viscosities at high temperature of 10⁴ dPa·s, 10³ dPa·s, and 10^{2.5} dPa·s are values measured by a platinum sphere pull up method.

The liquidus temperature TL is a temperature at which a crystal precipitates after glass powder that has passed through a standard 30-mesh sieve (500 μm) and remains on a 50-mesh sieve (300 μm) is placed in a platinum boat and kept for 24 hours in a gradient heating furnace.

The liquidus viscosity log₁₀ηTL is a value obtained by measuring the viscosity of the glass at the liquidus temperature TL by a platinum sphere pull up method.

As apparent from Table 1, each of Sample Nos. 1 to 12 is free of alkali metal oxides in the glass composition and has a Young's modulus of 84 GPa or more, a strain point of 740° C. or more, and a liquidus temperature of 1,285° C. or less, and is hence conceived to have satisfactory productivity, be able to reduce thermal shrinkage in an LTPS process, and be less liable to cause a defect due to deflection even when the glass sheet is increased in size and reduced in thickness. Accordingly, each of Sample Nos. 1 to 12 is suitable as a substrate for an OLED device.

### INDUSTRIAL APPLICABILITY

The alkali-free glass sheet of the present invention is suitable as a substrate of a display panel for an OLED device, particularly for an OLED TV, or as a carrier for manufacturing an OLED display panel. Other than those applications, the alkali-free glass sheet of the present invention is also suitable, for example, as a substrate for a flat panel display such as a liquid crystal display, a glass substrate for a magnetic recording medium, a cover glass for an image sensor, such as a charge coupled device (CCD) or a contact image sensor (CIS), a substrate and a cover glass for a solar cell, or a substrate for an OLED lighting device.

1. An alkali-free glass sheet, which has a content of Li₂O+Na₂₀+K₂O of from 0 mol % to 0.5 mol % in a glass composition, and has a Young's modulus of 80 GPa or more, a strain point of 700° C. or more, and a liquidus temperature of 1,350° C. or less.

2. An alkali-free glass sheet, comprising as a glass composition, in terms of mol %, 64% to 71% of SiO₂, 12% to 17% of Al₂O₃, 0% to 5% of B₂O₃, 0% to 0.5% of Li₂O+Na₂O+K₂O, 5% to 9% of MgO, 2% to 10% of CaO, 0% to 7% of SrO, more than 1% to 7% of BaO, and 14% to 20% of MgO+CaO+SrO+BaO, and having a molar ratio Al₂O₃/BaO of from 1.8 to 10, a molar ratio B₂O₃/(MgO+CaO+SrO+BaO) of from 0 to 0.2, a molar ratio (B₂O₃+MgO)/SiO₂ of from 0.1 to 0.2, and a molar ratio B₂O₃/MgO of from 0 to 0.5.

3. The alkali-free glass sheet according to claim 1, wherein the alkali-free glass sheet is further substantially free of As₂O₃ and Sb₂O₃.

4. The alkali-free glass sheet according to claim 1, wherein the alkali-free glass sheet further comprises 0.001 mol % to 1 mol % of SnO₂.

5. The alkali-free glass sheet according to claim 1, wherein the alkali-free glass sheet has a strain point of 710° C. or more.

6. The alkali-free glass sheet according to claim 1, wherein the alkali-free glass sheet has a Young's modulus of more than 81 GPa.

7. The alkali-free glass sheet according to claim 1, wherein the alkali-free glass sheet has an average thermal expansion coefficient within a temperature range of from 30° C. to 380° C. of from 30×10−7/° C. to 50×10−7/° C.

8. The alkali-free glass sheet according to claim 1, wherein the alkali-free glass sheet has a liquidus viscosity of 104.0 dPa·s or more.

9. The alkali-free glass sheet according to claim 1, wherein the alkali-free glass sheet is used for an OLED device.
